(19) United States
(12) Patent Application Publication
(10) Pub. No.: US 2005/0186753 A1
(43) Pub. Date: Aug. 25, 2005

(54) FIB exposure of alignment marks in MIM technology

(76) Inventors: Ping-Hsu Chen, Dongshih Township (TW); Ping Chuang, ChangGung Tsuen (TW); Mei-Sheng Zhou, Singapore (SG); Francis Ko, Taichung (TW); Huxley Lee, Hsin-Chu City (TW); Joshua Tseng, Hsin-Chu (TW); Henry Lo, Hsinchu (TW)

Correspondence Address: TUNG & ASSOCIATES, Suite 120, 838 W. Long Lake Road, Bloomfield Hills, MI, 48302, US

(21) Appl. No.: 10/786,187

(22) Filed: Feb. 25, 2004

(51) Int. Cl. H01L 21/76; H01L 21/302; H01L 21/461; G03F 9/00

(52) U.S. Cl. 438/401; 438/710; 438/711; 430/5

(57) ABSTRACT

A new and improved method for exposing alignment marks on a substrate by locally cutting through a metal or non-metal layer or layers sequentially deposited on the substrate above the alignment marks, using focused ion beam (FIB) technology. In a preferred embodiment, a method for exposing alignment marks on a substrate can be carried out by first providing a substrate that has multiple alignment marks provided thereon and at least one overlying opaque layer, typically but not necessarily metal, deposited on the substrate above the alignment marks. A focused ion beam is then directed against the overlying opaque layer or layers to cut through the layer or layers and expose the alignment marks on the substrate. A noble gas, preferably argon, is typically used as the ion source for the focused ion beam.

### FIELD OF THE INVENTION

The present invention generally relates to a method for exposing alignment marks on a substrate during the fabrication of a metal-insulator-metal capacitor on the substrate. More particularly, the present invention relates to a method for exposing alignment marks beneath an opaque metal or non-metal layer or film on a substrate by cutting through the layer or film using a focused ion beam (FIB).

### BACKGROUND

In the fabrication of semiconductor integrated circuits, metal conductor lines are used to interconnect the multiple components in device circuits on a semiconductor wafer. A general process used in the deposition of metal conductor line patterns on semiconductor wafers includes deposition of a conducting layer on the silicon wafer substrate; formation of a photoresist or other mask such as titanium oxide or silicon oxide, in the form of the desired metal conductor line pattern, using standard lithographic techniques; subjecting the wafer substrate to a dry etching process to remove the conducting layer from the areas not covered by the mask, thereby leaving the metal layer in the form of the masked conductor line pattern; and removing the mask layer typically using reactive plasma and chlorine gas, thereby exposing the top surface of the metal conductor lines. Typically, multiple alternating layers of electrically conductive and insulative materials are sequentially deposited on the wafer substrate, and conductive layers at different levels on the wafer may be electrically connected to each other by etching vias, or openings, in the insulative layers and filling the vias using aluminum, tungsten or other metal to establish electrical connection between the conductive layers.

A current drive in the semiconductor device industry is to produce semiconductors having an increasingly large density of integrated circuits which are ever-decreasing in size. These goals are achieved by scaling down the size of the circuit features in both the lateral and vertical dimensions. Vertical downscaling requires that the thickness of gate oxides on the wafer be reduced by a degree which corresponds to shrinkage of the circuit features in the lateral dimension. While there are still circumstances in which thicker gate dielectrics on a wafer are useful, such as to maintain operating voltage compatibility between the device circuits manufactured on a wafer and the current packaged integrated circuits which operate at a standard voltage, ultrathin gate dielectrics will become increasingly essential for the fabrication of semiconductor integrated circuits in the burgeoning small/fast device technology.

The ongoing advances in the field of fabricating miniaturized electronic integrated circuits (ICs) has involved the fabrication of multiple layers of interconnects, or the layers of separate electrical conductors which are formed on top of a substrate and connect various functional components of the substrate and other electrical connections to the IC. Electrical connections between the interconnect layers and the functional components on the substrate are achieved by via interconnects, which are post- or plug-like vertical connections between the conductors of the interconnect layers and the substrate. ICs often have five or more interconnect layers formed on top of the substrate.

Only a relatively short time ago, it was impossible or very difficult to construct an IC with more than one or two layers of interconnects. The topology variations created by forming multiple layers on top of one another resulted in such significant depth of focus problems with lithographic processes that any further additions of layers were neardly impossible to achieve. However, recent advances in semiconductor fabrication planarization techniques, such as chemical mechanical polishing (CMP), have been successful in smoothing relatively significant variations in the height or topography of each interconnect layer. As a result of the smoothing, or planarization, conventional lithographic processes are repetitively used without significant limitation to form considerably more layers of interconnects than had previously been possible.

The multiple interconnect layers occupy volume within the IC, although they do not necessarily occupy additional substrate surface area. Nevertheless, because surface area and volume are critical considerations in Ics, attention has been focused on the effective use of the space between the interconnect layers. Normally, the space between the interconnect layers is occupied by an insulating material, known as an interlayer dielectric (ILD) or intermetal dielectric (IMD), to insulate the electrical signals conducted by the various conductors of the interconnect layers from each other and from the functional components in the underlying substrate.

One effective use for the space between the interconnect layers is the incorporation of capacitors between the interconnect layers in the IMD insulating material separating the interconnect layers. These capacitors form part of the functional components of the IC. Previously, capacitors were constructed in the first layers of IC fabrication immediately above the substrate alongside other structures, such as transistors, so the capacitors were formed of generally the same material used to construct the other functional components, such as polysilicon. Capacitors formed of these materials are generally known as poly-plate capacitors.

Because the conductors of the interconnect layers are metal in construction, the capacitors formed between the interconnect layers are preferably of a metal-insulator-metal (MIM) construction to take advantage of processing steps and performance enhancements. A MIM capacitor has metal plates which are usually formed on the metal conductors of the interconnect layers. Because metal fabrication is required for the conductors of the interconnect layers, the simultaneous or near-simultaneous formation of the metal capacitor plates is readily accomplished without significant additional process steps and manufacturing costs.

MIM capacitors are very valuable in many applications of semiconductor technology. For example, MIMs can be used in RF circuits, analog ICs, high power microprocessor units (MPUs), and DRAM cells. However, alignment marks which lie at the junction of the substrate and the base dielectric layer deposited on the substrate and are important for semiconductor processing, are obscured by the opaque metal layers and transparent IMD layers that are sequentially deposited on the base dielectric layer and on each other. Thus, during fabrication of MIM capacitors it frequently becomes necessary to cut through the metal layers and the intervening dielectric layer or layers of the MIM capacitor to the transparent base dielectric layer on the substrate in order to expose the alignment marks through the layer.

A sectional view of a portion of a MIM capacitor 10 fabricated on a wafer substrate 12 is shown in FIG. 1. During fabrication of the MIM capacitor 10, a transparent base dielectric layer 14 is deposited on the substrate 12. Multiple alignment marks 16 are provided at the junction between the substrate 12 and the base dielectric layer 14 to facilitate proper alignment of the substrate 12 with various processing tool elements during semiconductor fabrication, as is known by those skilled in the art. An opaque bottom metal layer 18 is deposited on the base dielectric layer 14, after which an intermetal dielectric layer 20 is deposited on the bottom metal layer 18. Finally, a top metal layer 22 is deposited on the intermetal dielectric layer 20. As shown, the alignment marks 16 are obscured by the overlying opaque bottom metal layer 18 and top metal layer 22.

Conventional methods for re-exposing the alignment marks 16 after deposition of the metal layers 18, 22 on the substrate 12 include using standard photolithography techniques, in which a layer of photoresist 24 is initially patterned on the top metal layer 22. Next, photoresist stripping and etching techniques are used to remove aligned portions of the photoresist 24, the top metal layer 22, the intermetal dielectric layer 20 and the bottom metal layer 18, respectively, in order to expose the alignment marks 16 through the transparent base dielectric layer 14. However, this method is time-consuming, imprecise and produces supply bottlenecks under high-volume processing conditions. Accordingly, a new and improved method for the expeditious, precise and time-efficient re-exposure of alignment marks during MIM capacitor fabrication is needed. According to the method of the present invention, this is achieved using focused ion beam (FIB) technology.

In an FIB technique, focused ion beams are used to locally either deposit materials on or remove materials from a substrate. FIB utilizes a cluster of ionized beams consisting of an aggregate of from 100 to 2,000 atoms aimed at the substrate surface. When it impacts the surface of the substrate, the cluster disintegrates into atoms, which are then scattered over the surface of the substrate to remove a surface layer of the substrate material. Typical ion beams have a focused spot size of smaller than 100 nm when produced by a high-intensity source. Sources of such high-intensity ions can be either liquid metal ion sources or gas field ion sources. Both of these sources have a needle-type form that relies on field ionization or evaporation to produce the ion beam. After the ion beam is produced, it is deflected in a vacuum and directed to a desired surface area. The focused ion beams can be suitably used in semiconductor processing as a cutting or attaching tool to perform a circuit repair, a mask repair or a micro-machining process.

A FIB-mediated cutting or milling process is normally performed by sputtering a surface with a focused ion beam. In an ion beam milling process, where a material is selectively etched by a beam of ions such as Ga⁺ focused to a submicron diameter, the technique is often referred to as focused ion beam etching or milling. FIB milling is a very useful technique for restructuring a pattern on a mask or an integrated circuit, and for diagnostic cross-sectioning of micro structures. In a typical FIB etching process, a beam of ions such as Ga⁺ is incident onto a surface to be etched and the beam can be deflected to produce a desirable pattern. In the etch chamber, a gas such as Cl₂ can be introduced to fill the chamber to a pressure of about 30 mTorr, while the vacuum outside the chamber where the FIB is generated is normally maintained at approximately 10⁻⁷ Torr. The focused ion beam can be used to bombard a specimen surface at a very low angle, i.e., as low as 0-5 , such that a cavity can be formed on the surface of an electronic structure to reveal a characteristic feature of the structure for electron microscopic examination.

A typical focused ion beam arrangement is shown in FIG. 2. The FIB apparatus 30 includes a suppressor and a liquid metal ion source 32, wherein the liquid metal ion may be gallium; an ion extractor 34; a three-element assymetric lens 36, and an electrostatic aperture adjustment 38. The ion beam 40, after crossing at the electrostatic aperture adjustment 38, is treated by a second three-element asymmetric lens 42 before the ion beam 40 impinges on a target 44. The operating modes include a beam control pattern which intermittently blanks the ion beam and allows the ion charge to dissipate, thus reducing electrostatic discharge damage. The ion beam 40 is advantageously focused with a a column that includes the three-element asymmetric lens assembly 36 and 42. The ion beam 40 produced by the apparatus 30 has a superior position stability and high current density. The ion beam 40 further has a fine probe diameter and beam placement accuracy capable of high performance versatility of a full digital beam scanning process.

An object of the present invention is to provide a new and improved method for exposing alignment marks on a substrate.

Another object of the present invention is to provide a new and improved method for the expedited exposure of alignment marks obscured by opaque, metal layers such as copper or non-metal layers such as silicon nitride, poly silicon, and germanium, for example, deposited on a substrate.

Still another object of the present invention is to provide a new and improved method for cutting through stacked or non-stacked, opaque, metal or non-metal layers deposited on a substrate to expose alignment marks on the substrate beneath the layers.

Yet another object of the present invention is to provide a new and improved alignment mark exposure method which is suitable for but not limited to metal-insulator-metal (MIM) capacitor fabrication technology.

A still further object of the present invention is to provide a new and improved alignment mark exposure method which is suitable for exposing alignment marks beneath any type of opaque or substantially non-transparent film or layer deposited on a substrate.

Yet another object of the present invention is to provide a new and improved alignment mark exposure method which is suitable for exposing alignment marks covered by metal residue as a result of chemical mechanical planarization (CMP).

### SUMMARY OF THE INVENTION

In accordance with these and other objects and advantages, the present invention is generally directed to a new and improved method for exposing alignment marks on a substrate by cutting through opaque, metal or non-metal films or layers sequentially or individually deposited on the substrate above the alignment marks, using focused ion beam (FIB) technology.

In a preferred embodiment, a method for exposing alignment marks on a substrate can be carried out by first providing a substrate that has multiple alignment marks provided thereon and at least one overlying opaque layer, which may be a metal such as copper or an opaque semiconductor film such as silicon nitride, poly silicon or germanium, deposited on the substrate above the alignment marks. An FIB apparatus is then positioned over the substrate, above the alignment marks, after which an ion beam is directed against the overlying layer to cut through the layer and expose the alignment marks on the substrate. A noble gas, preferably argon, is typically used as the ion source for the focused ion beam, although other gases may be selected depending on the application. Alternatively, a liquid metal ion such as gallium may be used as the ion source. The current for the focused ion beam is typically at least about 400 pA.

### BRIEF DESCRIPTION OF THE DRAWINGS

The invention will now be described, by way of example, with reference to the accompanying drawings, in which:

FIG. 1 is a cross-sectional view of a portion of an MIM capacitor, illustrating a conventional technique for exposing alignment marks on the capacitor substrate;

FIG. 2 is a schematic illustrating a conventional focused ion beam apparatus;

FIG. 3A is a cross-sectional view of a portion of an MIM capacitor, with an opaque metal layer obscuring alignment marks on the capacitor substrate;

FIG. 3B is a cross-sectional view of the portion of the MIM capacitor of FIG. 3A, illustrating cutting of the opaque metal layer above the alignment marks to expose the alignment marks, using a focused ion beam in implementation of the present invention; and

FIG. 3C is a cross-sectional view of the portion of the MIM capacitor of FIG. 3A, after the alignment mark exposure process is completed.

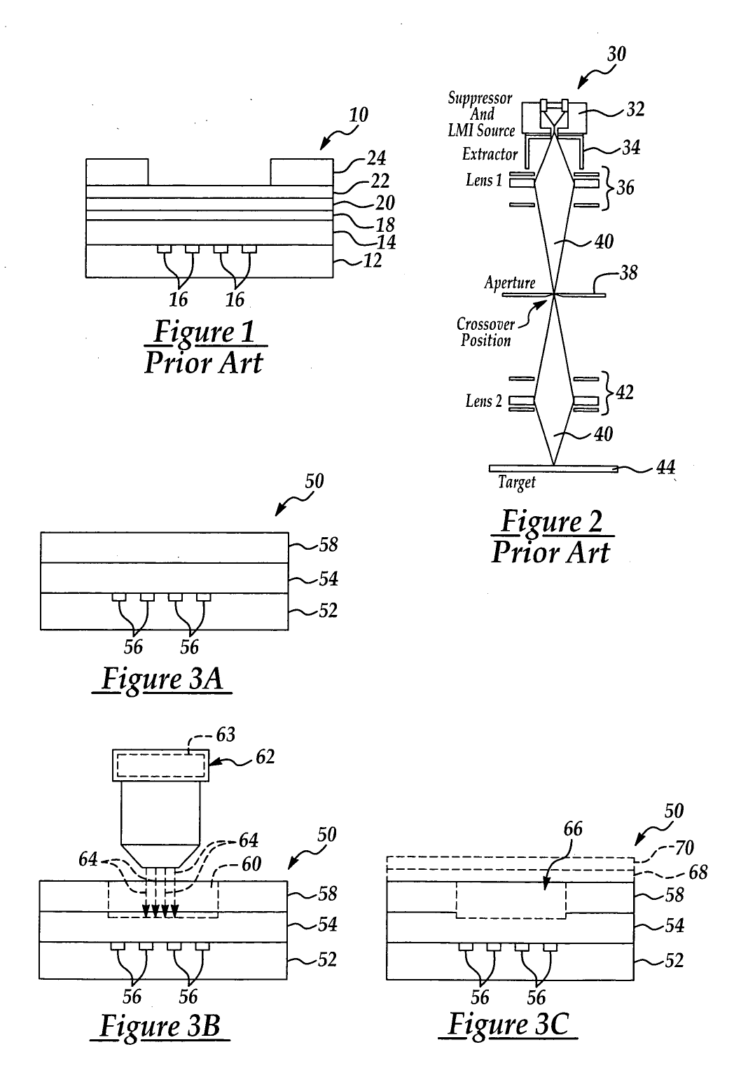

### DESCRIPTION OF THE PREFERRED EMBODIMENTS

The present invention includes a new and improved focused ion beam (FIB) method for exposing an alignment mark or marks which are covered or obscured by an opaque metal or non-metal layer or layers deposited on a substrate such as during the fabrication of an MIM (metal-insulator-metal) capacitor on the substrate. The method includes positioning the FIB apparatus over the opaque layer or layers which overlie the alignment marks and then providing an exposure opening in the layer or layers by cutting through the layer or layers typically to the transparent dielectric layer which directly overlays the alignment mark or marks on the substrate. Accordingly, the alignment marks are visible through the exposure opening in the layer or layers, to facilitate proper alignment of the substrate with processing tool elements during subsequent semiconductor processing.

The novel method of the present invention has particularly beneficial utility in the re-exposure of alignment marks obscured or covered on a substrate by the sequential deposition of metal and intermetal dielectric (IMD) layers in the course of fabricating an MIM capacitor on the substrate. However, it will be recognized and understood by those skilled in the art that the method may be used to re-expose alignment or other marks covered or obscured by individual or sequential deposition of material layers such as silicon nitride, poly silicon and germanium, in non-exclusive particular, during the course of other semiconductor processing or in other industrial processes.

The novel method of the present invention exploits the superior cutting control characteristics of a focused ion beam to provide enhanced accuracy and precision in defining the length, width and depth dimensions of the exposure opening through which the alignment marks on the substrate are to be made visible. The method is particularly advantageous for applications having critical dimensions smaller than 0.13 m. The method is much more time-efficient than the conventional photolithographic and etching techniques for re-exposing alignment marks on a substrate.

In a preferred embodiment, the novel method of the present invention contemplates the use of a noble gas, preferably argon, as an ion source in a conventional focused ion beam apparatus. In the FIB chamber, a gas such as Cl₂ can be introduced to fill the chamber to a pressure of about 30 mTorr, while the vacuum outside the chamber where the FIB is generated may be maintained at approximately 10⁻⁷ Torr. Alternatively, the FIB chamber may be maintained under vacuum to maintain cleanliness of the wafer surface. The current density for the focused ion beam may be at least about 400 pA, but may be adjusted according to the thickness of the layer or layers to be cut to form the exposure opening through which the alignment marks are to be made visible.

The method of the invention will be further described with reference to FIGS. 3A-3C, wherein a cross-section of a portion of a substrate. 52 having multiple alignment marks 56 is generally indicated by reference numeral 50. The substrate portion 50 may be an MIM capacitor, for example, or other structure being fabricated on the substrate 52. As shown in FIG. 3A, the substrate portion 50 includes a wafer substrate 52 having multiple cavities or pits that define alignment marks 56 in the upper surface of the substrate 52. A base dielectric layer 54, which is typically transparent silicon oxide, is deposited on the substrate 52, with the silicon oxide 54 material filling the cavities or pits that define the alignment marks 56. The base dielectric layer 54 is deposited on the substrate 52 typically according to conventional deposition processes which are well-known by those skilled in the art. Due to the transparency of the base dielectric layer 54, the alignment marks 56 are normally visible through the overlying base dielectric layer 54 such that the alignment marks 56 can be used to properly align and position the substrate 52 with alignment elements of processing tools during subsequent semiconductor processing.

The substrate portion 50 further includes an opaque layer 58 of copper or other electrically-conductive metal, in the event that the substrate portion 50 is an MIM capacitor, or an opaque layer of silicon nitride, poly silicon or germanium, for example, which is deposited on the base dielectric layer 54 typically using a conventional chemical or physical vapor deposition process. However, due to the opacity of the opaque layer 58, the underlying alignment marks 56 are covered or obscured by the opaque layer 58 and thereby prevent proper alignment and positioning of the substrate 52 in processing tools used to complete fabrication of the MIM capacitor or other structure being fabricated on the substrate portion 50 during subsequent processing steps. Accordingly, the alignment marks 56 must be re-exposed or uncovered for visible positional verification in order to resume fabrication of the MIM capacitor or other structure.

Referring next to FIG. 3B, after the opaque layer 58 is deposited on the base dielectric layer 54, the substrate 52 is placed in a conventional focused ion beam chamber (not shown) and etched by a typically high current density of approximately 400-800 pA in the vicinity of the alignment marks 56. The FIB apparatus 62 typically uses a noble gas, typically argon, as an ion source 63. When used as the ion source 63, argon gas enhances the etch rate and selectivity of the focused ion beams 64 emitted from the FIB apparatus 62. Alternatively, the ion source 63 may be a liquid metal ion such as gallium. Accordingly, the FIB apparatus 62 is initially positioned over the portion of the metal layer 58 which overlies the alignment marks 56. As the FIB process proceeds, the focused ion beams 64 uniformly etch away an opaque layer portion 60 corresponding to the entire thickness of the opaque layer 58, including possibly a thin slice of the underlying base dielectric layer 54. The progress of the material removal can be seen in a video monitor which indicates the layers that are removed in real time. The capability of the FIB apparatus 62 to provide viewing of the opaque layer 58 and base dielectric layer 54 in real time is of great benefit which further facilitates proper cutting away of the opaque layer portion 60. Furthermore, the current, voltage, size, ion flux and bombardment time of the focused ion beams 64 may be adjusted according to the knowledge of those skilled in the art to control the etching area of the focused ion beams 64. The bombardment area can be adjusted by tuning the ion beam size, the etching speed by tuning the ion flux, the etching depth by tuning the bombardment time, and the surface roughness by changing the ion energy and flux.

The focused ion beam cutting process continues until the base dielectric layer 54 appears in the video monitor of the FIB apparatus 62. At that point, the cutting process is terminated and an exposure opening 66 corresponding to the opaque layer portion 60 (FIG. 3B) removed from the opaque layer 58 extends through the thickness of the layer 58, as shown in FIG. 3C. Due to the transparency of the base dielectric layer 54, the alignment marks 56 are again visible through the base dielectric layer 54, rendering it possible for personnel to properly align and position the substrate 52 in processing tools for subsequent semiconductor processing. Fabrication of the MIM capacitor on the substrate portion 50 is completed typically by depositing a second dielectric layer 68 on the opaque metal layer 58, after which a second metal layer 70 is typically deposited on the second dielectric layer 68. At any point during the fabrication process, the second metal layer 70 or any other metal layer or layers sequentially deposited on the substrate 52 to fabricate the MIM capacitor may be cut using the focused ion beams 64, in the manner heretofore described with respect to FIG. 3B, in order to facilitate precise and time-efficient re-exposure of the alignment marks 56 on the substrate 52, as deemed necessary.

While the preferred embodiments of the invention have been described above, it will be recognized and understood that various modifications can be made in the invention and the appended claims are intended to cover all such modifications which may fall within the spirit and scope of the invention.

1. A method of exposing alignment marks on a substrate having at least one opaque overlaying the alignment marks, comprising the steps of:
providing a focused ion beam; and
exposing the alignment marks by impinging said focused ion beam against the at least one opaque layer to obliterate the at least one opaque layer substantially overlaying the alignment marks.

2. The method of claim 1 wherein said focused ion beam has a noble gas ion source.

3. The method of claim 1 wherein said focused ion beam has a current density of about 200-800 pA.

4. The method of claim 3 wherein said focused ion beam has a noble gas ion source.

5. The method of claim 2 wherein said noble gas ion source comprises argon.

6. The method of claim 5 wherein said focused ion beam has a current density of about 200-800 pA.

7. The method of claim 4 wherein said noble gas ion source comprises argon.

8. The method of claim 7 wherein said focused ion beam has a current density of about 200-800 pA.

9. A method of exposing alignment marks on a substrate having at least one opaque overlaying the alignment marks, comprising the steps of:
providing a focused ion beam; and
cutting an exposure opening in the at least one opaque layer to expose the alignment marks by impinging said focused ion beam against the at least one opaque layer.

10. The method of claim 9 wherein said focused ion beam has a noble gas ion source.

11. The method of claim 9 wherein said focused ion beam has a current density of about 200-800 pA.

12. The method of claim 11 wherein said focused ion beam has a noble gas ion source.

13. The method of claim 10 wherein said noble gas ion source comprises argon.

14. The method of claim 13 wherein said focused ion beam has a current density of about 200-800 pA.

15. The method of claim 12 wherein said noble gas ion source comprises argon.

16. A method of exposing alignment marks on a substrate having a transparent dielectric layer overlaying the alignment marks and at least one opaque layer overlying the dielectric layer, comprising the steps of:
providing a focused ion beam; and
cutting an exposure opening in the at least one opaque layer to the dielectric layer to visually expose the alignment marks by impinging said focused ion beam against the at least one opaque layer.

17. The method of claim 16 wherein said focused ion beam has a noble gas ion source.

18. The method of claim 16 wherein said focused ion beam has a current density of about 200-800 pA.

19. The method of claim 17 wherein said noble gas ion source comprises argon.

20. The method of claim 19 wherein said focused ion beam has a current density of about 200-800 pA.
